(19) United States
(12) Patent Application Publication
(10) Pub. No.: US 2020/0196433 A1
(43) Pub. Date: Jun. 18, 2020

(54) METHOD FOR MOUNTING COMPONENT

(71) Applicant: STMicroelectronics (Grenoble 2) SAS, Grenoble (FR)

(72) Inventors: David Auchere, Meylan (FR); Norbert Chevrier, Lumbin (FR); Fabien Quercia, Saint Marcelin (FR); Asma Hajji, Voiron (FR)

(21) Appl. No.: 16/691,231

(22) Filed: Nov. 21, 2019

(30) Foreign Application Priority Data
Dec. 13, 2018 (FR) 1872865

(51) Int. Cl. H05K 1/02; H05K 3/30; H01L 23/00

(52) U.S. Cl. CPC H05K 1/023; H05K 3/303; H01L 2924/12; H01L 2924/1659; H01L 24/45

(57) ABSTRACT

A method includes attaching a discrete component on a circuit board with a first glue, attaching an integrated circuit to the circuit board using a third glue, and attaching a cap to the circuit board using a second glue. The first glue has a composition such that it does not interact electrically with the second glue and does not interact electrically with the third glue.

### CROSS-REFERENCE TO RELATED APPLICATIONS

This application claims priority to French Application No. 1872865, filed on Dec. 13, 2018, which application is hereby incorporated herein by reference.

### TECHNICAL FIELD

The present disclosure relates generally to a method for mounting electronic components, e.g., on a circuit board.

### BACKGROUND

The mounting of electronic components on a circuit board can be realized in several different ways. One of these ways consists in directly soldering the contact(s) of the electronic component on the connection pads of the circuit board.

It would desirable to be able to at least partially improve certain aspects of the known methods for mounting components on a circuit board.

### SUMMARY

The present disclosure relates generally to a method for mounting electronic components on a circuit board. Particular embodiments relate to a method for mounting discrete components on a circuit board.

One embodiment provides a method comprising a step of gluing a discrete component on a circuit board with a first glue the composition of which is such that it interacts electrically neither with a second glue used for attaching a cap to the circuit board, nor with a third glue used for attaching one or more integrated circuits to the circuit board.

According to an embodiment, the first glue is an insulating glue.

According to an embodiment, the second glue is an insulating glue.

According to an embodiment, the first glue is identical to the second glue.

According to an embodiment, the third glue is an insulating glue.

According to an embodiment, the first glue is identical to the third glue.

According to an embodiment, the method further comprises a step of gluing the cap with the second glue on the circuit board.

According to an embodiment, the discrete component is a passive component.

According to an embodiment, the discrete component is a component comprising at least two contacts accessible from an upper face.

According to an embodiment, the second glue is an epoxy-type polyepoxide-based glue.

According to an embodiment, the third glue is an epoxy-type polyepoxide-based glue.

According to an embodiment, the discrete component is a surface-mount component.

According to an embodiment, the discrete component is a passive component.

A further embodiment provides the electronic circuit in which at least one discrete component is glued on a circuit board with a first glue the composition of which is such that it does not interact with a second glue used for attaching a cap to the circuit board and with a third glue used for attaching one or more integrated circuits to the circuit board.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates a top view of an embodiment of a circuit board;

FIG. 2A and FIG. 2B illustrate two sectional views of a portion of the circuit of FIG. 1; and

FIG. 3 illustrates a sectional view of a discrete component mounted on a circuit board.

### DETAILED DESCRIPTION OF ILLUSTRATIVE EMBODIMENTS

Like features have been designated by like references in the various figures. In particular, the structural and/or functional features that are common among the various embodiments may have the same references and may have identical structural, dimensional and material properties.

For the sake of clarity, only the operations and elements that are useful for an understanding of the embodiments described herein have been illustrated and described in detail.

Unless specified otherwise, when reference is made to two elements that are connected to each other, this means directly connected without any intermediate elements other than conductors, and when reference is made to two elements that are linked or coupled to each other, this means that these two elements can be connected or be linked or coupled by way of one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

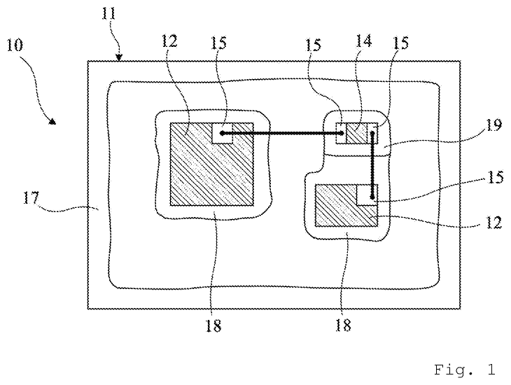

FIG. 1 is a top view of an embodiment of a circuit 10.

The circuit 10 is composed of a circuit board 11 on which electronic components are mounted. More particularly, the circuit board 11 comprises on its upper face and/or its lower face electronic components, e.g., one or more integrated circuits 12 (two integrated circuits are illustrated in FIG. 1) and one or more discrete components 14 (a single discrete component is illustrated in FIG. 1). The discrete components 14 are, for example, surface-mount components (SMC), e.g., transistor, thyristor, diode, etc. and/or, for example, passive components, e.g., capacitors, resistors, etc. Each electronic component 12, 14 comprises one or more contacts 15. The circuit board 11 is, for example, a printed circuit board or a component substrate.

The circuit 10 is, moreover, generally covered by a protective cap (not shown in FIG. 1). The cap is, for example, glued to the perimeter region of the circuit board 11 by means of a glue 17. The shape of a layer of the glue 17 is shown in FIG. 1. The layer of the glue 17 covers the perimeter region of the circuit board with a non-negligible thickness. The glue 17 is, for example, an insulating or conductive epoxy-type polyepoxide-based glue, e.g., a glue known under the trade name Henkel 8387.

According to an alternative embodiment, it would be possible for the circuit not to be covered by a cap, but rather exhibit, in lieu of the layer of glue 17, a layer of epoxy resin surrounding and covering the components of the circuit 10.

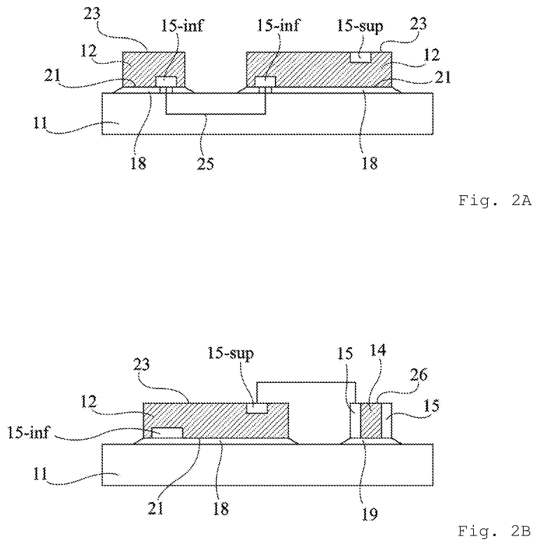

The contacts 15 of the integrated circuits 12 are, for example, arranged on an upper face and/or a lower face of the latter. The contacts 15 arranged on the lower surface are, for example, soldered directly to the connecting terminals of the circuit board (see FIG. 2). The contacts 15 arranged on the upper face are, for example, connected to other contacts by a wire bonding method (see FIG. 2). The integrated circuits 12 are glued directly on the circuit board 11 with a glue 18. The shape of the layer of the glue 18 is illustrated in FIG. 1. The layers of the glue 18 cover a portion or the entirety of the lower surface of the integrated circuit 12, and extend beyond, for example, the integrated circuit 12. The glue 18 is, for example, a conductive or insulating epoxy-type polyepoxide-based glue, e.g., a glue known under the trade name Henkel 2100A.

According to an embodiment, the discrete components 14 are glued directly on the circuit board 11 by means of a layer of glue 19. The glue 19 is a glue that does not interact electrically with the glues 17 and 18. In other words, when the glues 17 and/or 18 are insulating, the glue 19 is an insulating glue that can be in contact with the glues 17 and 18, and when the glues 17 and/or 18 are conductive glues, the glue 19 cannot be in contact with the glues 17 and/or 18. More specifically, the glue 19 is an insulating glue, e.g. an insulating epoxy-type glue. According to an embodiment, the glue 19 can be the same glue as the glue 17, or 18, provided that it is insulating, and, in this case, a discrete component 14 can be glued on the circuit board 11 with the same layer of glue as the integrated circuit 12. The contacts 15 of the components 14 are connected to other contacts by a wire bonding method. In FIG. 1, a discrete component is illustrated that comprises two contacts 15; however, other types of discrete components are conceivable.

One method for manufacturing the circuit 10 is the following. The components 12 and 14 are glued on the circuit board by way of the layers of glue 18 and 19. Several components 12, or 14, can be glued by way of the same layer of glue. The connections necessary for the operation of the circuit 10 are realized, for example, by using a wire bonding method. Once the circuit 10 is operational, a protective cap can be glued on the circuit board 11 by way of the layer of glue 17 which is formed on the outer edge of the circuit board 11.

One advantage of gluing discrete components 14 on the circuit board 11 is that it makes it possible to place a discrete component 14 closer to an integrated circuit 12 on a circuit board. Indeed, the discrete components are generally soldered to connection pads of a circuit board. A disadvantage of soldering is that it forces certain design rules to be observed so as to avoid the solder touching the layer(s) of glue used to attach other components to the circuit board and/or used to attach the cap on the perimeter region of the circuit board. Avoiding the use of solder thus makes it possible to reduce design constraints and thus to increase the number of components per circuit board or else to reduce the surface of the latter.

FIG. 2A and 2B each illustrate a way of connecting two mounted components of the circuit 10 on a circuit board 11.

FIG. 2A illustrates a way of connecting contacts of two integrated circuits 12. Each integrated circuit comprises, for example, one or more contacts 15-inf accessible from its lower face 21 and/or one or more contacts 15-sup accessible from its upper face 23.

A preferred example of a way of connecting two contacts 15-inf of two different integrated circuits 12 is the following. Each contact 15-inf is connected, for example by soldering or brazing, to an end of a via 25 that traverses the circuit board 11. The integrated circuit 12 is, in this case, glued to the circuit board 11 with a layer of the glue 18 arranged between the integrated circuit 12 and the board 11. In the case where the integrated circuit 12 comprises a plurality of contacts 15-inf, the glue 18 is insulating so as to avoid short-circuiting the contacts 15-inf between each other. Moreover, the layer of the glue 18 can, for example, comprise openings at the connections of the contacts 15-inf.

Another example of a way of connecting (not shown) contacts 15-inf of several different integrated circuits is the following. In the case where the contacts 15-inf are coupled to a same terminal or to a same potential, e.g. the ground, the glue 18 can be electrically conductive. The layer of glue 18 thus acts as a conductor.

FIG. 2B illustrates a way of connecting contacts of a discrete component 14 and another component, e.g. an integrated circuit 12. The integrated circuit 12 comprises the same elements as the integrated circuits 12 described in relation to FIG. 2A. The discrete component 14 has, for example, the shape of a rectangular parallelepiped and comprises two contacts 15 arranged on opposite lateral faces of the component and accessible from either face of the component. More specifically, each contact 15 of the discrete component is at least accessible by the upper face 26 of the component 14.

A preferred example of a way of connecting a contact 15 of a discrete component 14 to a contact 15-sup of the integrated circuit 12 is the following. The two contacts are connected by a wire bonding method. A wire bonding method is a method in which a contact is connected to another by a bondwire. More precisely, a first end of the bondwire is bonded to a first contact then the second end of the bondwire is bonded to a second contact.

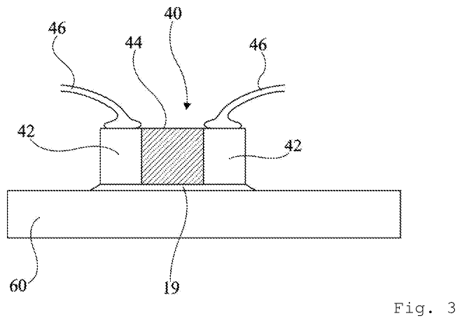

FIG. 3 is a sectional view of a discrete component 40 mounted on a circuit board 50 of the same type as the circuit board 11.

The discrete component 40 is of the same type as the component 14 described in relation to FIG. 2B, i.e., the discrete component 40 comprises at least two contacts 42 accessible from its upper face 44. In the case illustrated in FIG. 3, the contacts 42 each cover a portion of the lower face of the component 40.

The component 40 is mounted on a circuit board 60 of the same type as the circuit board 11 described in relation to FIGS. 1 and 2. As described in the preceding figures, the component 40 is glued directly to the board 60 by way of a layer of the glue 19 deposited between the lower face 33 of the component and the upper face of the board 50. In order to avoid connecting the contacts 42 to each other, the glue 19 is electrically insulating.

The contacts 42 are each connected to another contact (not illustrated in FIG. 3) by way of a bondwire 46 positioned by a wire bonding method.

Various embodiments and variants have been described. Those skilled in the art will understand that certain features of these different embodiments can be combined and other variants will readily occur to those skilled in the art. In particular, only discrete components comprising two contacts have been described, but these embodiments also apply to discrete components comprising more than two contacts, such as, for example, a transistor.

Finally, the practical implementation of the embodiments and variants described herein is within the capabilities of those skilled in the art based on the functional description provided above.

What is claimed is:

1. A method comprising:
attaching a discrete component on a circuit board with a first glue;
attaching an integrated circuit to the circuit board using a third glue; and
attaching a cap to the circuit board using a second glue, wherein the first glue has a composition such that it does not interact electrically with the second glue and does not interact electrically with the third glue.

2. The method according to claim 1, wherein the first glue is an electrically insulating glue.

3. The method according to claim 2, wherein the first glue is identical to the second glue.

4. The method according to claim 1, wherein the second glue is an electrically insulating glue.

5. The method according to claim 1, wherein the third glue is an electrically insulating glue.

6. The method according to claim 5, wherein the first glue is identical to the third glue.

7. The method according to claim 1, wherein the discrete component is a passive component.

8. The method according to claim 1, wherein the discrete component is a component comprising a plurality of contacts accessible from an upper face that faces away from the circuit board.

9. The method according to claim 1, wherein the second glue is an epoxy-type polyepoxide-based glue.

10. The method according to claim 1, wherein the third glue is an epoxy-type polyepoxide-based glue.

11. The method according to claim 1, wherein the discrete component is a surface-mount component.

12. A method comprising:
attaching a discrete component to a circuit board with a first glue, the discrete component having first and second electrical contacts that extend from a bottom surface of the discrete component to a top surface of the discrete component, the bottom surface facing the circuit board and the top surface opposite the bottom surface;
attaching a first integrated circuit to the circuit board using a second glue;
attaching a second integrated circuit to the circuit board using the second glue, wherein the first glue has a composition such that it does not interact electrically with the second glue;
wire bonding the first electrical contact of the discrete component to a contact on a top surface of the first integrated circuit; and
wire bonding the second electrical contact of the discrete component to a contact on a top surface of the second integrated circuit.

13. The method according to claim 12, further comprising attaching a cap to the circuit board using a third glue, wherein the first glue does not interact electrically with the third glue.

14. The method according to claim 12, wherein the first glue is an electrically insulating glue and wherein the second glue is an electrically insulating glue.

15. The method according to claim 12, wherein the first glue is identical to the second glue.

16. The method according to claim 12, wherein the discrete component is a passive component.

17. The method according to claim 12, wherein the second glue is an epoxy-type polyepoxide-based glue.

18. An electronic circuit comprising:
a circuit board;
a discrete component glued on the circuit board with a first glue;
an integrated circuit glued on the circuit board with a second glue; and
a cap attached to the circuit board with a third glue, wherein the first glue has a composition such that the first glue does not interact with the second glue and does not react to the third glue.

19. The electronic circuit according to claim 18, wherein the discrete component has first and second electrical contacts that each extend from a bottom surface of the discrete component to a top surface of the discrete component, the bottom surface facing the circuit board and the top surface opposite the bottom surface.

20. The electronic circuit according to claim 19, further comprising a first bond wire connected between the first electrical contact of the discrete component and a contact on a top surface of the integrated circuit.

21. The electronic circuit according to claim 20, further comprising a second integrated circuit glued to the circuit board and a second bond wire connected the second electrical contact of the discrete component and a contact on a top surface of the second integrated circuit.

22. The electronic circuit according to claim 18, wherein the second glue is an epoxy-type polyepoxide-based glue.
